(19) United States
(12) Patent Application Publication
(10) Pub. No.: US 2026/0215043 A1
(43) Pub. Date: Jul. 23, 2026

(54) SEMICONDUCTOR DEVICE AND DISPLAY DEVICE HAVING THE SAME

(71) Applicant: EPISTAR CORPORATION, Hsinchu (TW)

(72) Inventors: Jih-Kang CHEN, Hsinchu (TW); Po-Wen HSIAO, Hsinchu (TW); Ching-Hua SU, Hsinchu (TW); Chen OU, Hsinchu (TW)

(21) Appl. No.: 19/028,245

(22) Filed: Jan. 17, 2025

(51) Int. Cl. H10H 20/854; H01L 25/075; H10H 20/819; H10H 20/841

(52) U.S. Cl. CPC H10H 20/854; H10H 20/819; H10H 20/841; H10W 90/00

(57) ABSTRACT

A semiconductor device includes a semiconductor stack, a stack structure and a covering layer. The semiconductor stack is stacked along a stacking direction and includes an active region and a sidewall, wherein an angle between the sidewall and a reference plane perpendicular to the stacking direction is between 60 degrees and 90 degrees. The stack structure covers the semiconductor stack and has a crack on the sidewall. In addition, the covering layer covers the stack structure, thereby the crack on the sidewall is covered by the covering layer.

### BACKGROUND

### Technical Field

The present disclosure relates generally to a semiconductor device and a display device having the same, and more particularly to a light-emitting diode device.

### Description of the Related Art

The light-emitting diode (LED) device is a sort of solid-state semiconductor device, which has the characteristics of low power consumption, low heat generation, long lifetime, small size, high response speed, and stable emission wavelength. Therefore, light-emitting diode devices have been widely used in household appliances, equipment indicator lights, optoelectronic products, and so forth. Recently, micro-LED devices are developed for display devices. However, the current micro-LED devices still cannot satisfy the requirements in all aspects.

### SUMMARY

In view of this, the present disclosure provides a semiconductor device and a display device having the same.

According to some embodiments of the present disclosure, a semiconductor device is provided and includes a semiconductor stack, a stack structure and a covering layer. The semiconductor stack is stacked along a stacking direction and includes an active region and a sidewall, wherein an angle between the sidewall and a reference plane perpendicular to the stacking direction is between 60 degrees and 90 degrees. The stack structure covers the semiconductor stack and has a crack on the sidewall. In addition, the covering layer covers the stack structure, and the crack on the sidewall is covered by the covering layer.

According to some embodiments of the present disclosure, a display device is provided and includes a plurality of pixel units, wherein at least one of the pixel units includes the aforementioned semiconductor device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a schematic cross-sectional view of a semiconductor device according to some embodiments of the present disclosure.

FIG. 2 shows enlarged schematic cross-sectional views of an area A in the semiconductor device of FIG. 1 according to some embodiments of the present disclosure.

FIG. 3 shows a schematic cross-sectional view of a semiconductor device according to some embodiments of the present disclosure.

FIG. 4, FIG. 5 and FIG. 6 show schematic cross-sectional views of some stages of a method of fabricating a semiconductor device according to some embodiments of the present disclosure.

FIG. 7 shows a schematic top view of a display device having the semiconductor device according to some embodiments of the present disclosure.

FIG. 8 shows a schematic cross-sectional view of a pixel unit in the display device of FIG. 7 according to some embodiments of the present disclosure.

### DETAILED DESCRIPTION OF THE EMBODIMENTS

The following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

Furthermore, as disclosed herein, the term “electrically connected to” includes any directly and indirectly electrical connecting means. Therefore, if it is described in this document that a first component is electrically connected to a second component, it means that the first component may be directly connected to the second component, or may be indirectly connected to the second component through other components or other connecting means.

In the present disclosure, if not specifically mention, the general expression of AlGaN means AlₐGa₍₁₋ₐ₎N, wherein 0≤a≤1; the general expression of InGaN means In_{b}Ga_{(1-b)}N, wherein 0≤b≤1; the general expression of AlInGaN means Al_{c}In_{d}Ga_{(1-c-d)}N, wherein 0≤c≤1, 0≤d≤1; the general expression of AlInGaP means (AlₑIn₍₁₋ₑ₎)_{1-f}Ga_{f}P, wherein 0≤e≤1, 0≤f≤1; the general expression of InGaAsP means In_{g}Ga_{1-g}AsₕP₁₋ₕ, wherein 0≤g≤1, 0≤h≤1; the general expression of AlGaAsP means (AlᵢGa₍₁₋ᵢ₎)AsⱼP₍₁₋ⱼ₎, wherein 0≤i≤1, 0≤j≤1; and the general expression of InGaAsP means (InₖGa₍₁₋ₖ₎)AsₗP₍₁₋ₗ₎, wherein 0≤k≤1, 0≤l≤1. The content of the element may be adjusted for different purposes, such as, adjusting the energy gap or the peak wavelength of the light emitted from semiconductor stacks.

The compositions and dopants of each layer in the semiconductor stacks of the present disclosure may be determined by any suitable means, such as secondary ion mass spectrometer (SIMS).

The thickness of each layer in the semiconductor devices disclosed in the present disclosure may be analyzed by suitable means, such as transmission electron microscopy (TEM) or scanning electron microscope (SEM), thereby corresponding to, for example, the depth position of each layer on the SIMS map.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

According to some embodiments of the present disclosure, a semiconductor device includes a stack structure formed on a semiconductor stack. The semiconductor device has a mesa structure with an acute angle greater than 60 degrees, and a crack is formed in the stack structure on the sidewall of the semiconductor stack. A covering layer is provided to prevent the stack structure from damage along the crack during the fabrication of the semiconductor device.

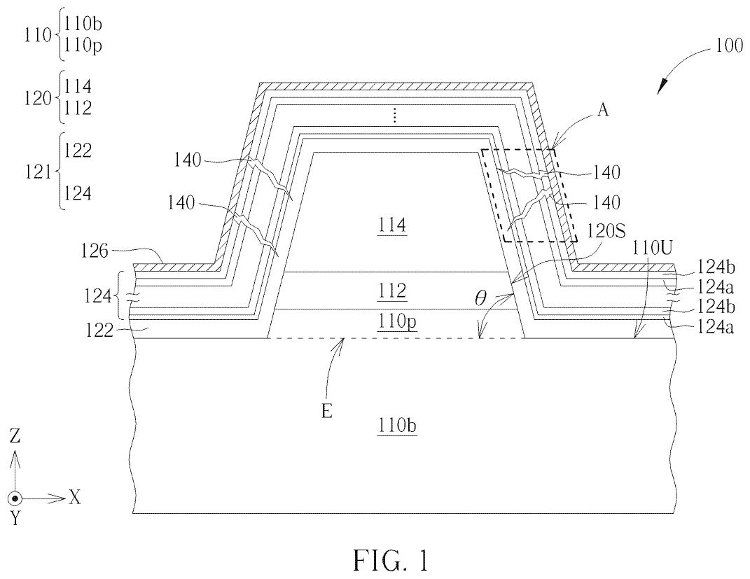

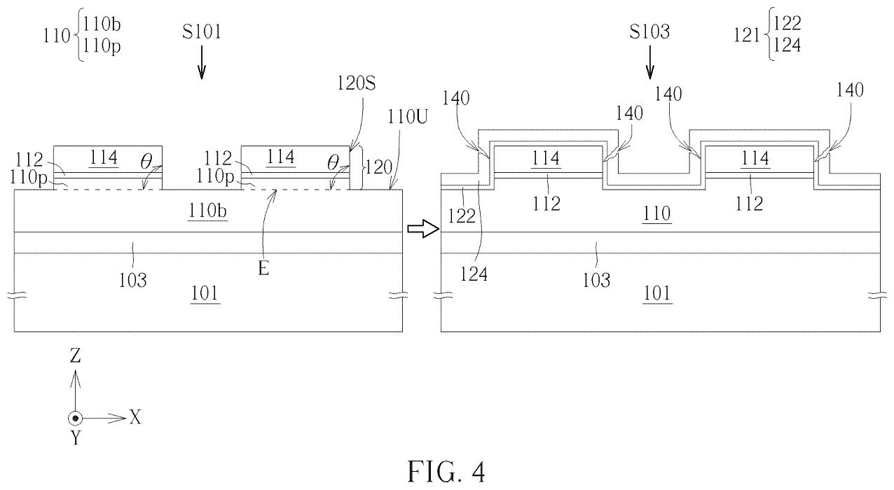

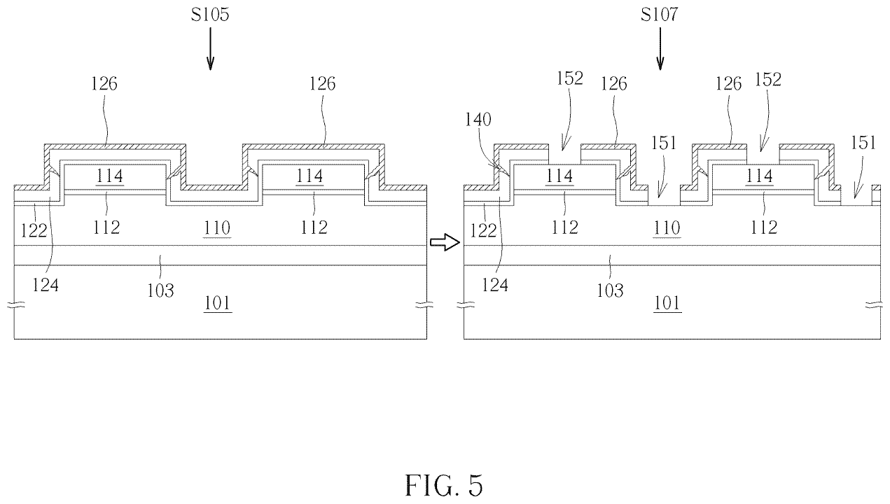

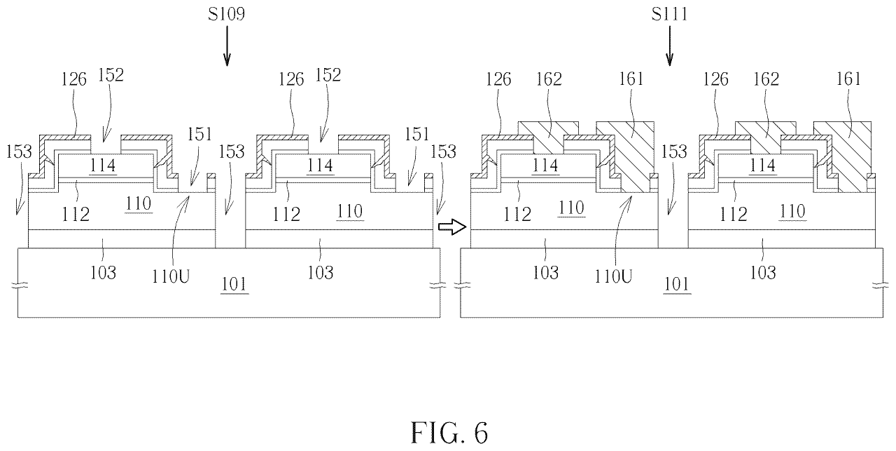

FIG. 1 shows a schematic cross-sectional view of a semiconductor device 100 according to some embodiments of the present disclosure. In order to make the figure concise and easy to understand, some features of the semiconductor device 100, such as a substrate, a first electrode and a second electrode, are not shown in FIG. 1. These features of the semiconductor device 100 may refer to FIG. 4, FIG. 5 and FIG. 6.

As shown in FIG. 1, the semiconductor device 100 includes a first semiconductor layer 110, a semiconductor stack 120, a stack structure 121 and a covering layer 126. The first semiconductor layer 110 includes a base portion 110b and a protrusion 110p protruded from the base portion 110b. The semiconductor stack 120 is formed on the protrusion 110p, and the base portion 110b has an upper surface 110U devoid of the protrusion 110p thereon. The stack structure 121 and the covering layer 126 cover the semiconductor stack 120 and the upper surface 110U. In some embodiments, the stack structure 121 and the covering layer 126 may further cover the sidewalls of the first semiconductor layer 110 (not shown).

The semiconductor stack 120 includes an active region 112 and a second semiconductor layer 114 stacked in sequence along a stacking direction such as the Z-axis direction. As shown in FIG. 1, the semiconductor stack 120 has a sidewall 120S, and an angle θ between the sidewall 120S and a reference plane E (the XY-plane) perpendicular to the stacking direction (the Z-axis direction) is between 60 degrees and 90 degrees. The reference plane E may be extended from the upper surface 110U of the first semiconductor layer 110. In other words, the semiconductor device 100 includes a mesa structure with an acute angle of 60 degrees and 90 degrees. The mesa includes the semiconductor stack 120 and the protrusion 110p.

The first semiconductor layer 110 and the second semiconductor layer 114 have opposite conductivity types, different electrical properties, different polarities or different dopants for providing electrons or holes. For example, the first semiconductor layer 110 includes n-type semiconductor and the second semiconductor layer 114 includes p-type semiconductor or the first semiconductor layer 110 includes p-type semiconductor and the second semiconductor layer 114 includes n-type semiconductor. The active region 112 is formed between the second semiconductor layer 114 and the protrusion 110p of the first semiconductor layer 110.

When being driven by a current, electrons and holes are combined in the active region 112 to convert electrical energy into optical energy for illumination. The wavelength of the light generated by the semiconductor device 100 can be adjusted by changing the physical properties and chemical composition of one or more layers in the semiconductor stack 120. The semiconductor device 100 may be a light-emitting diode (LED) device.

The material of the semiconductor stack 120 includes III-V semiconductor with AlGaN or AlInGaP. When the material of the semiconductor stack 120 includes AlInGaP, the semiconductor stack 120 emits red light having a wavelength between 570 nm and 780 nm or yellow light having a wavelength between 550 nm and 570 nm. When the material of the semiconductor stack 120 includes InGaN, the semiconductor stack 120 emits blue light or deep blue light having a peak wavelength between 380 nm and 490 nm, green light having a peak wavelength between 490 nm and 550 nm or red light having a peak wavelength between 560 nm and 660 nm. The semiconductor device 100 may be a single hetero-structure (SH), a double hetero-structure (DH), a double-side double hetero-structure (DDH), or a multi-quantum well (MQW) structure. The material of the active region 112 may be i-type, p-type or n-type semiconductor.

The stack structure 121 is formed to cover the semiconductor stack 120. The stack structure 121 includes a base layer 122 and a reflective structure 124, such as distributed Bragg reflector (DBR), disposed on the base layer 122. The base layer 122 may be silicon oxide (SiO₂) or silicon nitride (SiNₓ), and formed by chemical vapor deposition (CVD) such as plasma enhanced chemical vapor deposition (PECVD). The thickness of the base layer 122 may be between 1500 Å and 10000 Å. The reflective structure 124 includes multiple pairs of a first layer 124a and a second layer 124b stacked alternately, and may be formed by physical vapor deposition (PVD) such as electron beam evaporation. The first layer 124a and the second layer 124b have different refractive indexes, and may be selected from a group consisting of silicon oxide (SiO₂), titanium oxide (TiO₂), niobium oxide (Nb₂O₅), magnesium fluoride (MgF₂) and silicon nitride (SiNₓ). The respective thicknesses of the first layer 124a and the second layer 124 b may be between 300 Å and 2000 Å. In the stack structure 121, the thickness of the base layer 122 is thinner than the total thickness of the reflective structure 124.

The angle θ of the semiconductor stack 120 is greater than 60 degrees and the stack structure 121 is formed of multiple layers by multiple deposition processes. Therefore, a crack 140 is easily formed in the stack structure 121 on the sidewall 120S of the semiconductor stack 120. The crack 140 may be formed within the reflective structure 124. More specifically, the crack 140 extends toward inside from an outside surface of the reflective structure 124. In some embodiments, the crack 140 may further extend into the base layer 122. The crack 140 is not parallel to the sidewall 120S of the semiconductor stack 120. The crack 140 may have a maximum width less than 300 nm.

The covering layer 126 covers the stack structure 121, and the crack 140 on the sidewall is also covered by the covering layer 126. The covering layer 126 is formed or conformally formed on the sidewall of the stack structure 121 to cover the crack 140. The covering layer 126 may be aluminum oxide (Al₂O₃) or aluminum nitride (AlN) and made by atomic layer deposition (ALD). The thickness of the covering layer 126 may be between 200 Å and 1000 Å. Density is a characteristic of a material, which is defined by the ratio of the total atomic volume to the cell volume in one unit cell. The density of the covering layer 126 is greater than the density of the reflective structure 124 including of SiO₂ and TiO₂ and formed by PVD. The density of the base layer 122 including SiO₂ or SiNx and formed by CVD is also greater than the density of the reflective structure 124. In some embodiments, the density of the covering layer 126 is greater than the density of the stack structure 121.

In some embodiments, the thickness of the covering layer 126 is thinner than that of the base layer 122. In some embodiments, the thickness of the covering layer 126 is thinner than or equal to that of the first layer 124a or the second layer 124b of the reflective structure 124. The thickness of the covering layer 126 is thinner than the total thickness of the reflective structure 124.

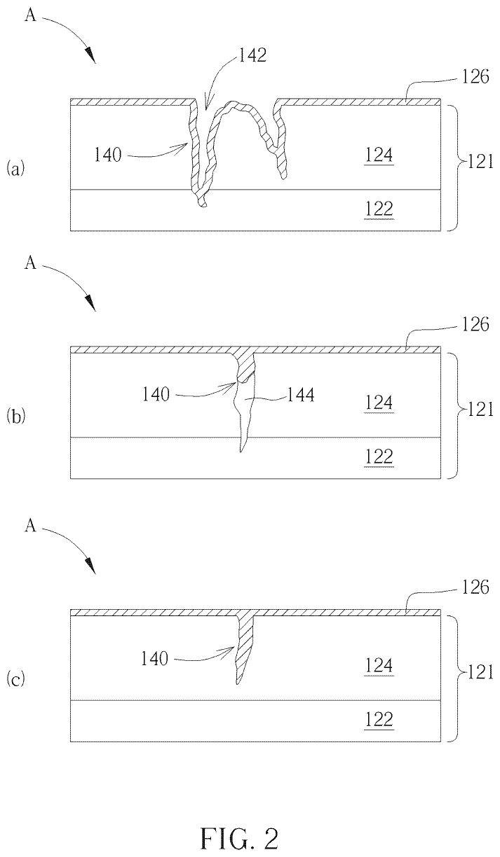

FIG. 2 shows enlarged schematic cross-sectional views of an area A in the semiconductor device 100 of FIG. 1 according to some embodiments of the present disclosure. As shown in (a) of FIG. 2, a plurality of cracks 140 (such as two) is formed in the stack structure 121, where one crack 140 is located in the reflective structure 124 and does not extend into the base layer 122, and another crack 140 is located in the reflective structure 124 and further extends into the base layer 122. The covering layer 126 covers or conformally covers the cracks 140 and recesses 142 are formed corresponding to the cracks 140. Since the covering layer 126 conformally covers the cracks 140 and the density of the covering layer 126 is greater than that of the reflective structure 124, the covering layer 126 can prevent chemical gas and/or liquid from entering into the stack structure 121 along the cracks 140.

As shown in (b) of FIG. 2, the crack 140 is formed in the stack structure 121, located in the reflective structure 124 and extends into the base layer 122. The crack 140 may have a high aspect ratio, and the covering layer 126 covers the crack 140 or/and fills into the crack 140. In some embodiments, the covering layer 126 does not fill up the crack 140 and a void 144 is formed. The covering layer 126 covers the crack 140 and isolates the void 144 from the outside environment. Therefore, the covering layer 126 can prevent chemical gas and/or liquid from entering into the stack structure 121 along the crack 140 and/or through the void 144.

As shown in (c) of FIG. 2, the crack 140 is formed in the stack structure 121, located in the reflective structure 124 and does not extend into the base layer 122. The covering layer 126 fills up the crack 140 without a void in the stack structure 121. Therefore, the covering layer 126 can prevent chemical gas and/or liquid from entering into the stack structure 121 through the crack 140.

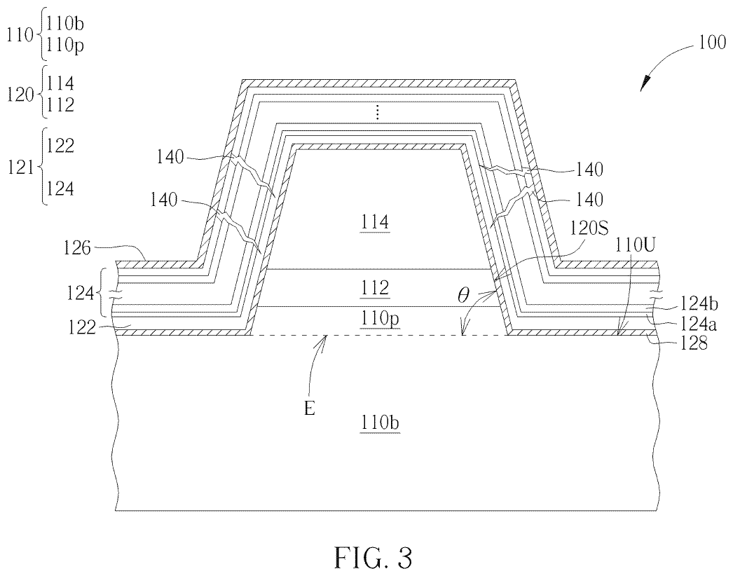

FIG. 3 shows a schematic cross-sectional view of a semiconductor device 100 according to some embodiments of the present disclosure. In some embodiments, the semiconductor device 100 further includes a protective layer 128 disposed between the semiconductor stack 120 and the stack structure 121 and between the first semiconductor layer 110 and the stack structure 121. The protective layer 128 covers or conformally covers the semiconductor stack 120 and the upper surface 110U of the first semiconductor layer 110. In some embodiments, the materials of the covering layer 126 and the protective layer 128 are the same and includes Al₂O₃ or AlN. In some embodiments, the protective layer 128 may be formed by ALD. The thickness of the protective layer 128 may be between 200 Å and 1000 Å.

The thickness of the protective layer 128 may be thinner than that of the base layer 122. The thickness of the protective layer 128 may be also thinner than or equal to the thickness of the first layer 124a or the second layer 124b of the reflective structure 124. In some embodiments, the thickness of the protective layer 128 may be thinner than the total thickness of the reflective structure 124. In addition, the density of the protective layer 128 is greater than that of the reflective structure 124. The density of the protective layer 128 is also greater than that of the base layer 122. The protective layer 128 protects the semiconductor stack 120 from damaging by chemical gas and/or liquid during the subsequent fabrication of the semiconductor device. The details of the other features of the semiconductor device 100 in FIG. 3 may refer to the aforementioned description of the semiconductor device 100 in FIG. 1, and are not repeated herein.

FIG. 4, FIG. 5 and FIG. 6 are schematic cross-sectional views of some stages of a method of fabricating a semiconductor device 100 according to some embodiments of the present disclosure. Referring to FIG. 4, in step S101, firstly, a base101 is provided for carrying semiconductor layers thereon. In some embodiments, the base 101 may be a growth substrate. For example, the base 101 may include GaAs or GaP for growing the AlInGaP or AlGaAsP semiconductor thereon. Alternatively, the base 101 may include sapphire, GaN, SiC, or Si for growing the AlInGaN semiconductor such as GaN, InGaN or AlGaN thereon. Alternatively, the base 101 may include InP for growing the InGaAsP semiconductor thereon.

An intermediate structure 103 is formed on the base 101. In some embodiments, the intermediate structure 103 is a semiconductor buffer structure. In some embodiments, the buffer structure is for reducing the lattice mismatch and suppresses dislocation so as to improve the epitaxy quality. The material of the intermediate structure 103 includes GaN, AlGaN, or AlN. In some embodiments, the intermediate structure 103 includes a plurality of sub-layers (not shown) and the sub-layers include the same materials or different materials. In some embodiments, the intermediate structure 103 includes two sub-layers wherein a first sub-layer thereof is grown by sputtering and a second sub-layer thereof is grown by metal-organic chemical vapor deposition (MOCVD). In another embodiment, the intermediate structure 103 further includes a third sub-layer. The third sub-layer is grown by MOCVD, and the growth temperature of the second sub-layer is higher or lower than the growth temperature of the third sub-layer. In some embodiments, the first, second, and third sub-layers include the same material, such as AlN. Next, a first semiconductor layer 110, an active region 112 and a second semiconductor layer 114 are formed in sequence along a stacking direction such as the Z-axis direction by metal-organic chemical vapor deposition (MOCVD), molecular beam epitaxy (MBE), hydride vapor epitaxy (HVPE) or ion plating such as sputtering or evaporating, thereby forming an epitaxial stack on the intermediate structure 103. The base 101 may be a patterned substrate that includes a plurality of patterned structures (not shown) on the upper surface where the intermediate structure 103 formed thereon. The patterned structures of the base 101 may lessen or suppress the dislocation by lattice mismatch between the base 101 and the intermediate structure 103, thereby improving the epitaxy quality of the semiconductor stack 120. The base 101 will be removed, and the patterned structures of the base 101 can be transferred to the intermediate structure 103. The light generated from the semiconductor stack 120 can be scattered by the patterned structures of the intermediate structure 103, thereby suppressing the total internal reflection effect.

In some embodiments, the base 101 is a bonding substrate and the intermediate structure 103 is a bonding structure. The epitaxial stack may be firstly grown on a growth substrate, and the epitaxial stack can be bonded to the base 101 via the intermediate structure 103, then the growth substrate can be removed from the epitaxial stack.

As shown in FIG. 4, the second semiconductor layer 114, the active region 112 and a portion of the first semiconductor layer 110 are etched to form a mesa structure including the second semiconductor layer 114, the active region 112 and the protrusion 110p. The first semiconductor layer 110 has an upper surface 110U devoid of the protrusion 110p thereon. The semiconductor stack 120 has a sidewall 120S. In some embodiments, an angle θ between the sidewall 120S and a reference plane E (the XY-plane) perpendicular to the stacking direction (the Z-axis direction) is 90 degrees.

Then, still referring to FIG. 4, in step S103, a base layer 122 is formed or conformally formed on the semiconductor stack 120 and the upper surface 110U of the first semiconductor layer 110.

Thereafter, a reflective structure 124 is formed on the base layer 122. In some embodiments, the reflective structure 124 may be formed by electron beam evaporation and includes three to ten pairs of a first layer 124a and a second layer 124b stacked alternately as shown in FIG. 1 and FIG. 3. The first layer 124a and the second layer 124b have different compositions and include SiO₂ and TiO₂, respectively.

In some embodiments, the protective layer 128 as shown in FIG. 3 is optionally formed on the semiconductor stack 120 and the upper surface 110U of the first semiconductor layer 110 before forming the base layer 122.

Next, referring to FIG. 5, in step S105, a covering layer 126 is formed or conformally formed on the stack structure 121. The covering layer 126 formed by ALD has a step coverage capacity and a gap fill ability to conformally cover the stack structure 121 and cover the cracks 140 in the stack structure 121. In some embodiments, the covering layer 126 may be Al₂O₃. The covering layer 126 can form a continuous protection structure for the semiconductor stack 120.

Then, still referring to FIG. 5, in step S107, a first opening 151 and a second opening 152 are formed in the stack structure 121 and the covering layer 126 by an etching process to expose the first semiconductor layer 110 and the second semiconductor layer 114, respectively. During the etching process of forming the first opening 151 and the second opening 152, the covering layer 126 prevents the etching gas and/or liquid from entering the stack structure 121 along the cracks 140. Therefore, the covering layer 126 can protect the stack structure 121 and the semiconductor stack 120 from damage.

Next, referring to FIG. 6, in step S109, the intermediate structure 103, the first semiconductor layer 110, the stack structure 121 and the covering layer 126 are etched to form a trench 153 for isolation, thereby separating multiple semiconductor devices from each other on the base 101. During the etching process of forming the trench 153, the covering layer 126 prevents the etching gas and/or liquid from entering the stack structure 121 along the cracks 140. The covering layer 126 can protect the stack structure 121 and the semiconductor stack 120 from damage in the subsequent fabrication processes.

Then, still referring to FIG. 6, in step S111, a first electrode layer 161 and a second electrode layer 162 are formed in the first opening 151 and the second opening 152, respectively, to complete the semiconductor device 100. The first electrode layer 161 is electrically connected to the first semiconductor layer 110. The second electrode layer 162 is electrically connected to the second semiconductor layer 114. The first electrode layer 161 and the second electrode layer 162 may cover a portion of the covering layer 126. The first electrode layer 161 and the second electrode layer 162 may be formed by deposition and patterning processes. Each of the first electrode layer 161 and the second electrode layer 162 may include metal or transparent conductive material. The metal material forms a thin metal layer having light transparency. The transparent conductive material is transparent to the light emitted from the active region 112, such as graphene, indium tin oxide (ITO), zinc aluminum oxide (AZO), gallium zinc oxide (GZO), zinc oxide (ZnO) or indium zinc oxide (IZO).

In addition, the first electrode layer 161 or/and the second electrode layer 162 includes a pad electrode and optionally includes finger electrodes (not shown) extending from the pad electrode. The pad electrodes of the first electrode layer 161 and the second electrode layer 162 are used for wire bonding or soldering bonding to electrically connect the semiconductor device 100 with an external power source or external electronic components. The materials of the first electrode layer 161 and the second electrode layer 162 include metals, such as Cr, Ti, Au, Al, Cu, Sn, Ni, Rh, W, In, Pt, an alloy of the above materials. The first electrode layer 161 and the second electrode layer 162 may include a single layer or multiple layers. For example, the first electrode layer 161 and the second electrode layer 162 may include Ti/Au, Ti/Pt/Au, Cr/Au, Cr/Pt/Au, Ni/Au, Ni/Pt/Au,

### Cr/al/cr/ni/au, Etc.

In some embodiments, the semiconductor device 100 further includes a current blocking layer (not shown) located between the second electrode layer 162 and the second semiconductor layer 114, and/or located between the first electrode layer 161 and the first semiconductor layer 110.

In some embodiments, the upper surface 110U for disposing the first electrode layer 161 and the surface of second semiconductor layer 114 for disposing the second electrode layer 162 face the same direction. The first electrode layer 161 and the second electrode layer 162 are connected to a carrier (not shown) by flip-chip bonding. The semiconductor device 100 is electrically connected to the circuit (not shown) on the carrier to be coupled with other electronic components or a power supply.

In some embodiments, the first electrode layer 161 and the second electrode layer 162 are respectively disposed on two opposite sides of the first semiconductor layer 110 or the semiconductor stack 120 or the base 101. Specifically, the first electrode layer 161 is disposed under the bottom surface of the first semiconductor layer 110. The second electrode layer 162 is disposed on the upper surface of the second semiconductor layer 114.

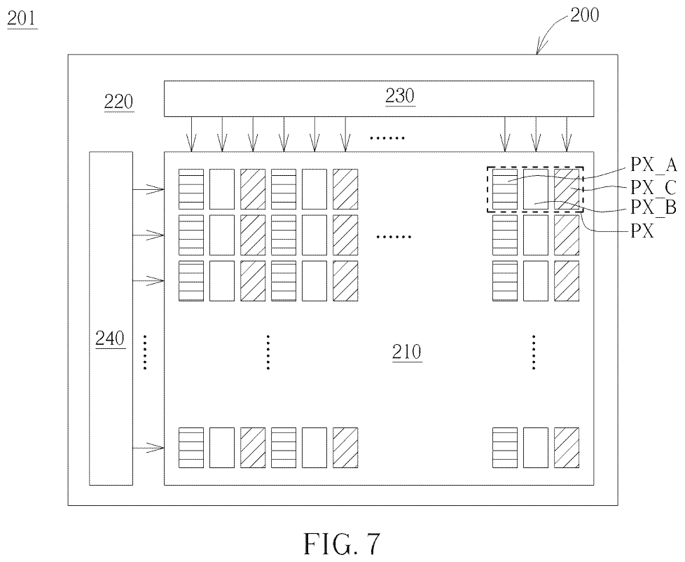

FIG. 7 is a schematic top view of a display device 201 having the semiconductor devices 100 according to some embodiments of the present disclosure. As shown in FIG. 7, the display device 201 includes a display panel 200, where the display panel 200 includes a display area 210 and a non-display area 220, and a plurality of pixel units PX are arranged in the display area 210. At least one of the pixel units PX includes the semiconductor device 100 of the above embodiments. Each of the pixel unit PX includes a first sub-pixel PX_A, a second sub-pixel PX_B, and a third sub-pixel PX_C. A data driver 230 and a scanning driver 240 are provided in the non-display area 220. The data driver 230 is connected to a data line (not shown) of each pixel unit PX to transmit a data signal to each pixel unit PX. The scanning driver 240 is connected to a scanning line (not shown) of each pixel unit PX to transmit a scanning signal to each pixel unit PX. The pixel unit PX includes the semiconductor device 100 in accordance with the above embodiments of the present disclosure, which includes the covering layer 126 to cover the cracks 140 in the stack structure 121. In some embodiments, in order to realize high resolution, the display device 201 includes the plurality of pixel units PX arranged in fine pitch. Therefore, the semiconductor device 100 in the pixel unit PX has a diagonal length smaller than 300 μm.

The sub-pixels emit lights of different colors. In some embodiments, the first sub-pixel PX_A, the second sub-pixel PX_B, and the third sub-pixel PX_C are, such as a first sub-pixel emitting red light, a second sub-pixel emitting green light, and a third sub-pixel emitting blue light, respectively. The semiconductor devices 100 emitting lights of different peak wavelengths are different sub-pixels so that the sub-pixels emit different colors. The combination of red, green, and blue light generated by each sub-pixel allows the display device 201 to display a full-color image.

However, the number and arrangement of the sub-pixels in the pixel unit PX in some embodiments can be varied, and different modes can be implemented according to user's requirements such as color saturation, resolution, and contrast. In accordance with some embodiments, the pixel unit PX further includes a fourth sub-pixel, and the fourth sub-pixel includes the semiconductor device 100 in accordance with any of the above embodiments of the present disclosure. The peak wavelength of the semiconductor device in the fourth sub-pixel is different from that of the semiconductor devices in the first to third sub-pixels. For example, the fourth sub-pixel is a cyan sub-pixel, and the semiconductor device in the fourth sub-pixel has a peak wavelength ranged between 495 nm and 520 nm. In one embodiment, the peak wavelength of the semiconductor device in the fourth sub-pixel is between 500 nm and 510 nm.

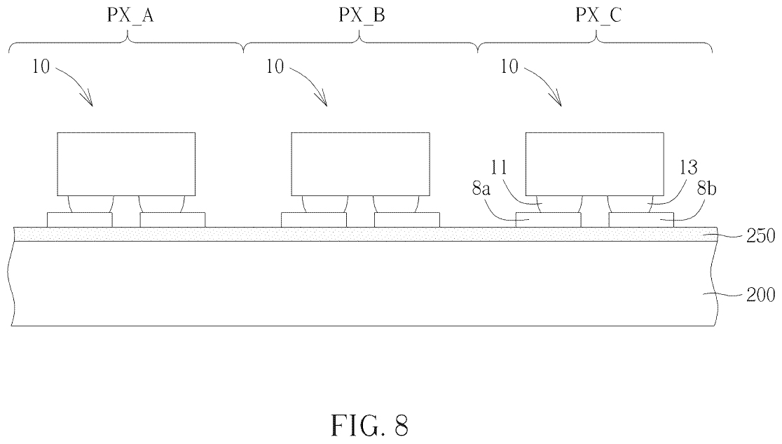

FIG. 8 shows a cross-sectional view of the pixel unit PX in the display device 201 of FIG. 7 according to some embodiments of the present disclosure. The semiconductor device 100 in the embodiment of FIG. 1 or FIG. 3 is encapsulated in a light-emitting package 10 and the light-emitting package 10 constitutes any one of the sub-pixels. The light-emitting package 10 is bonded to the display panel 200 in a flip-chip form. A circuit layer 250 and bonding pads 8a and 8b are located on the display panel 200. The circuit layer 250 is electrically connected to the bonding pads 8a and 8b. In on embodiment, the circuit layer 250 includes active components, such as transistors. The package electrode layers 11 and 13 of the light-emitting package 10 are bonded to the bonding pads 8a and 8b by soldering, and are electrically connected to the driving circuit (i.e., the data driver 230 and the scanning driver 240) through the circuit layer 250. In this way, the data driver 230, the scanning driver 240, and the circuit layer 250 control the semiconductor devices 100 in the pixel unit PX.

According to the embodiments of the present disclosure, the covering layer 126 conformally covers the stack structure 121 and covers the cracks 140, thereby preventing the etching gas and/or liquid used in the subsequent processes from entering into the stack structure 121 along the cracks 140. Moreover, the covering layer 126 and the stack structure 121 together construct a continuous protection layer to protect the semiconductor stack 120 from damage during the subsequent fabrication, such as a lift-off process for removing the base 101, a transfer process for multiple semiconductor devices 100, etc. Therefore, the photoelectric characteristics and the reliability of the semiconductor devices are improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a semiconductor stack, stacking along a stacking direction and comprising an active region and a sidewall, wherein an angle between the sidewall and a reference plane perpendicular to the stacking direction is between 60 degrees and 90 degrees;
a stack structure, covering the semiconductor stack and having a crack on the sidewall; and
a covering layer, covering the stack structure, thereby the crack on the sidewall is covered.

2. The semiconductor device of claim 1, further comprising a first semiconductor layer having a protrusion protruded therefrom, wherein the semiconductor stack is formed on the protrusion, and the first semiconductor layer has an upper surface devoid of the protrusion thereon, wherein the stack structure and the covering layer further cover the upper surface of the first semiconductor layer.

3. The semiconductor device of claim 2, wherein the semiconductor stack further comprises a second semiconductor layer on the active region, and the first semiconductor layer and the second semiconductor layer have opposite conductivity types.

4. The semiconductor device of claim 1, wherein a density of the covering layer is greater than a density of the stack structure.

5. The semiconductor device of claim 1, wherein the covering layer conformally covers the crack and has a recess corresponding to the crack.

6. The semiconductor device of claim 1, wherein the stack structure comprises a base layer and a reflective structure disposed on the base layer.

7. The semiconductor device of claim 6, wherein the crack extends into the base layer.

8. The semiconductor device of claim 6, wherein a thickness of the covering layer is thinner than that of the base layer.

9. The semiconductor device of claim 6, wherein the base layer comprises silicon oxide or silicon nitride.

10. The semiconductor device of claim 6, wherein the reflective structure comprises a plurality of pairs of a first layer and a second layer stacked alternately, and the first layer and the second layer have different refractive indexes.

11. The semiconductor device of claim 10, wherein a thickness of the covering layer is thinner than or equal to that of the first layer or the second layer.

12. The semiconductor device of claim 10, wherein the first layer and the second layer comprise silicon oxide, titanium oxide, niobium oxide, magnesium fluoride and silicon nitride.

13. The semiconductor device of claim 1, wherein the covering layer comprises aluminum oxide or aluminum nitride.

14. The semiconductor device of claim 1, further comprising a protective layer disposed between the semiconductor stack and the stack structure, wherein the protective layer covers the semiconductor stack.

15. The semiconductor device of claim 14, wherein materials of the covering layer and the protective layer are the same.

16. The semiconductor device of claim 15, wherein materials of the covering layer and the protective layer comprise aluminum oxide or aluminum nitride.

17. The semiconductor device of claim 1, wherein the covering layer covers the crack to have a void in the stack structure.

18. The semiconductor device of claim 1, wherein the covering layer fills up the crack.

19. A display device, comprising a plurality of pixel units, wherein one of the pixel units comprises the semiconductor device according to claim 1.

20. The display device of claim 19, wherein each of the pixel units comprising a first sub-pixel emitting red light, a second sub-pixel emitting green light and a third sub-pixel emitting blue light.
